(19) United States
(12) Patent Application Publication
(10) Pub. No.: US 2007/0067690 A1
(43) Pub. Date: Mar. 22, 2007

(54) Dynamic miscompare

(75) Inventors: Michael D. McPartland, Westford, MA (US); Nicholas A. Rediess, Marshfield, MA (US)

Correspondence Address: HAMILTON, BROOK, SMITH & REYNOLDS, P.C., 530 VIRGINIA ROAD, P.O. BOX 9133, CONCORD, MA, 01742-9133, US

(73) Assignee: Avidyne Corporation, Lincoln, MA (US)

(21) Appl. No.: 11/509,987

(22) Filed: Aug. 25, 2006

Related U.S. Application Data
(60) Provisional application No. 60/711,973, filed on Aug. 26, 2005.

(51) Int. Cl. G06F 11/00; G01R 31/28

(52) U.S. Cl. 714/736

(57) ABSTRACT

A dynamic miscompare module indicates instrumentation datum reliability by comparing a calculated difference between received instrumentation data and a total of a measured change in the received instrumentation data and a threshold value. The comparison varies dynamically with the measured change in the received instrumentation data. In an event the calculated difference exceeds the total, there is a miscompare condition and the related instrumentation datum is unreliable. The dynamic miscompare module alerts an operator of the condition by indicating a miscompare message indicator. The indicator is formed from a miscompare cue and a miscompare descriptor. The dynamic miscompare module further indicates the condition by interposing a leader between the miscompare message indicator and the unreliable instrumentation datum. Alternatively, the dynamic miscompare module locates the miscompare message indicator proximal to the unreliable instrumentation datum. Such telling and informative indication enables the operator to react to the miscompare condition effectively and accurately.

### RELATED APPLICATIONS

This application claims the benefit of U.S. Provisional Application No. 60/711,973 filed on Aug. 26, 2005, the entire teachings of which are herein incorporated by reference.

### BACKGROUND OF THE INVENTION

In the field of avionics, the technique of comparing two or more sets of data from similar or identical data sensors is employed to determine the reliability of an instrumentation datum. For example, data from two or more engine indicating systems (EIS), data from two or more attitude heading systems (AHS), or data from two or more air data systems (ADS) are inputted into a Primary Flight Display (PFD). Comparators inside the PFD compare datum from one system against datum from another like system, e.g., EIS₁ versus EIS₂. A significant difference between like systems indicates instrumentation datum from at least one system is erroneous and cannot be relied upon. A “miscompare” condition is said to have arisen.

An operator (e.g., a pilot) is alerted of a miscompare condition by the PFD. The operator may then interrogate other instrumentation data to evaluate the reasonableness of the suspect instrumentation datum. Should the operator determine that the suspect instrument datum is unreliable; the operator may then deselect or otherwise exclude that datum from the PFD.

The operator may be alerted to a miscompare condition in various ways. For example, an ‘ATT’ indicator is normally displayed on a PFD in the absence of a

The operator may be alerted to a miscompare condition in various ways. For example, an ‘ATT’ indicator is normally displayed on a PFD in the absence of a miscompare condition, i.e., there is no significant difference between attitude data. If however, pitch data (one measure of attitude) varies by X degrees, where the absolute value of X is greater than a set threshold value, then a miscompare warning indicator ‘PIT’ may be displayed in yellow, replacing the ‘ATT’ indicator. Additionally, if roll data (another measure of attitude) varies by Y degrees, where the absolute value of Y is greater than a set threshold value, then a miscompare warning indicator ‘ROL’ may be displayed in yellow, replacing the ‘ATT’ indicator.

A third possible miscompare condition exists. If both pitch data and roll data vary by X and Y degrees, where the absolute values of X and Y are greater than their respective thresholds, then an indicator ‘ATT’ may be displayed in yellow to indicate a miscompare condition. In summary, the operator is alerted to a miscompare condition when the PFD no longer indicates ‘ATT’ and either indicates ‘PIT’, ‘ROL’ or ‘ATT’ in yellow.

### SUMMARY OF THE INVENTION

Previous methods for evaluating reliability of an instrumentation datum require an operator (e.g., a pilot) to first determine whether there is a difference between data provided by two or more similar or like systems. That is, the operator must first determine whether a miscompare condition exists before the operator can evaluate the reliability of the instrumentation datum.

Using the example provided in the previous section, the color yellow indicates that a miscompare condition exists. While the operator is alerted to the miscompare condition, the operator does not know which instrumentation datum raised the miscompare condition, i.e., the operator does not known which instrumentation datum cannot be relied upon. Further deciphering by the operator is required to determine which instrumentation datum cannot be relied upon.

Again using the pervious example, the operator must know that a yellow ‘PIT’ indicator indicates a miscompare in pitch data while a yellow ‘ROL’ indicator indicates a miscompare in roll data. Furthermore, the operator must know that a yellow ‘ATT’ indicator signifies a miscompare in both pitch and roll data. Consequently, the operator is tasked with deciphering an indicator to ascertain the reliability of an instrumentation datum.

Ordinarily, an operator may carry out the task of deciphering such an indicator as a matter of routine or even as a reflex. However, when faced with a myriad of indicators and instrumentation data, all provided concurrently on a PFD, the operator may be overwhelmed and unable to decipher an each indicator effectively. The operator's ability to decipher an indicator may be further limited when multiple miscompare conditions arise. Consequently, the operator's ability to react to a miscompare condition effectively is compromised.

Contrastingly, a dynamic miscompare module in accordance with the principles of the present invention, alerts an operator to a miscompare condition in a more discernable, ascertainable, and comprehendible manner than previously available.

A method and an apparatus for indicating instrumentation datum reliability is provided. A method according to an example embodiment of the present invention includes: i) receiving a plurality of instrumentation data, ii) calculating a difference in the received plurality of instrumentation data, iii) measuring over time a change in the received plurality of instrumentation data, iv) comparing the calculated difference with a total of the measured change and a threshold value, v) and indicating a miscompare message indicator when the calculated difference exceeds the total of the measured change and the threshold value, the indicated miscompare message indicator providing an indication of reliability of an instrumentation datum.

A leader may be interposed between the indicated miscompare message indicator and the instrumentation datum. Alternatively, the indicated miscompare message indicator may be located proximally to the instrumentation datum.

Interposing a leader between a miscompare message indicator and an instrumentation datum allows an operator to readily discern, ascertain, and comprehend which instrumentation datum is unreliable. Similarly, locating a miscompare message indicator proximally to an instrumentation datum allows an operator to readily discern, ascertain, and comprehend which instrumentation datum is unreliable.

The indicated miscompare message indicator may be formed by a miscompare cue and a miscompare descriptor. The miscompare cue may be shaped as a rectangle, a square, an ellipse, a circle, a triangle or a polygon. Alternatively, the miscompare cue may be shaped as a callout balloon. The miscompare descriptor may be printed as English text, non-English text, an alphanumerical character string or a combination thereof.

Forming an indicated miscompare message indicator as a miscompare cue and a miscompare descriptor allows an operator to readily discern, ascertain, and comprehend which instrumentation datum is unreliable. For example, shaping the miscompare cue as a rectangle alerts an operator of a miscompare condition visually. As another example, printing the miscompare descriptor as English text alerts an operator of a miscompare condition textually.

In another embodiment of the present invention, a method for indicating instrumentation datum reliability includes: i) receiving a first instrumentation datum and at least one second instrumentation datum, ii) calculating a difference between the first instrumentation datum and at least one second instrumentation datum to determine a calculated difference, iii) measuring over time a change in the first instrumentation datum and at least one second instrumentation datum to determine a measured changed, iv) comparing the calculated difference with a total of the measured change and a threshold value, v) and indicating a miscompare message indicator to indicate the reliability of an instrumentation datum in an event the calculated difference exceeds the total of the measured change and the threshold value.

### BRIEF DESCRIPTION OF THE DRAWINGS

The foregoing and other objects, features and advantages of the invention will be apparent from the following more particular description of preferred embodiments of the invention, as illustrated in the accompanying drawings in which like reference characters refer to the same parts throughout the different views. The drawings are not necessarily to scale, emphasis instead being placed upon illustrating the principles of the invention.

FIG. 1A is a screen view of a flight display in accordance with one embodiment of the present invention;

FIG. 1B is a screen view of a flight display in accordance with one embodiment of the present invention;

FIG. 2 is a block diagram of an exemplary Primary Flight Display system (PFD) including an exemplary dynamic miscompare module in accordance with one embodiment of the present invention;

FIG. 3 is a flowchart of a dynamic miscompare module in accordance with one embodiment of the present invention;

FIG. 4 is an illustration of miscompare message indicator; and

FIG. 5 is a block diagram of an exemplary dynamic miscompare module in accordance with one embodiment of the present invention.

### DETAILED DESCRIPTION OF THE INVENTION

A description of preferred embodiments of the invention follows.

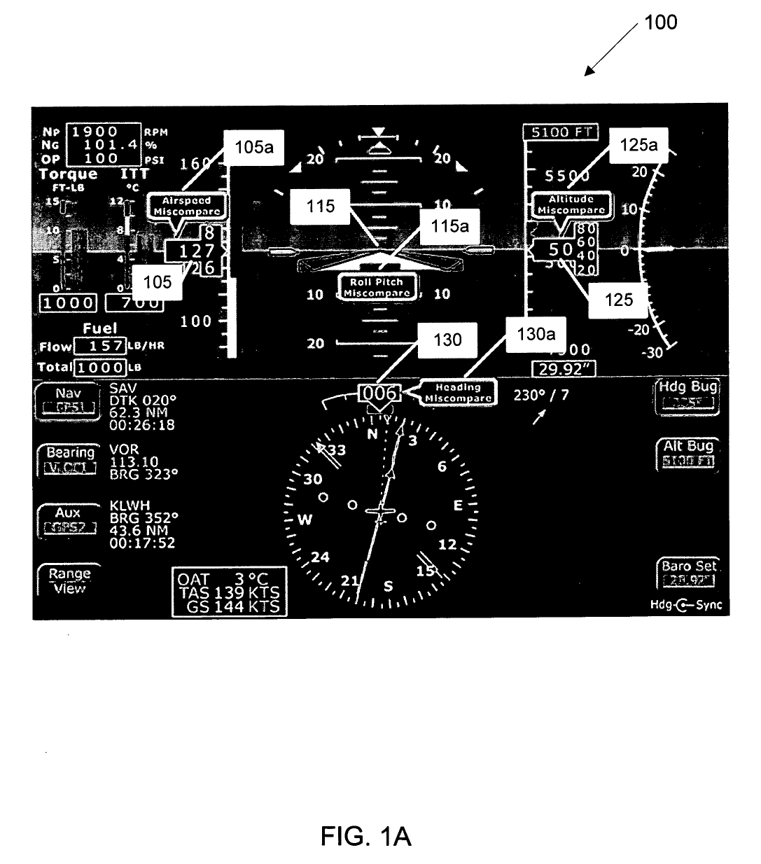

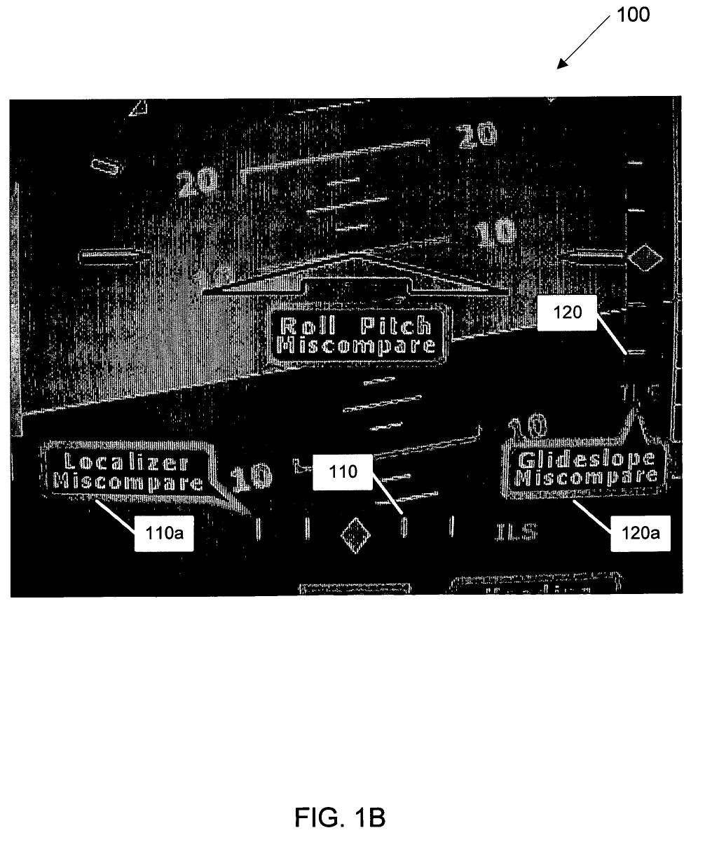

When operating a vehicle, an operator depends on the reliability of the instrumentation data presented. For example, when flying an aircraft, a pilot or a copilot may use instrumentation data as shown in FIGS. 1A and 1B to a fly the aircraft. An exemplary Primary Flight Display (PFD) system 100 presents or otherwise indicates an airspeed datum 105, a localized datum 110, a roll/pitch datum 115, a glideslope datum 120, an altitude datum 125 and a heading datum 130. Additionally, the PFD 100 may also present or otherwise indicate an airspeed miscompare message indicator 105a, a localized miscompare message indicator 110a, a roll/pitch miscompare message indicator 115a, a glideslope miscompare message indicator 120a, an altitude miscompare message indicator 125a, and a heading miscompare message indicator 130a, in addition to the aforementioned instrumentation data.

A miscompare message indicator (e.g., 105a, 110a, 115a, 120a, 125a, or 130a) alerts the operator that instrumentation datum (e.g., 105, 110, 115, 120, 125, or 130) is not reliable and that the operator should exercise caution when relying on such instrumentation datum. For example, if the airspeed miscompare message indicator 105a is indicated in conjunction with the airspeed datum 105, the operator is alerted that the airspeed datum 105 cannot be relied upon. Conversely, if the airspeed miscompare message indicator 105a is not indicated in conjunction with the airspeed datum 105 (i.e., PFD system 100 only displays the airspeed datum 105) the operator may rely on the airspeed datum 105.

The miscompare message indicators (e.g., 105a, 110a, 115a, 120a, and 130a) may be an alphanumerical character string, English text, non-English text or a combination thereof. Additionally, the miscompare message indicators (e.g., 105a, 110a, 115a, 120a, and 130a) may further include symbols and graphics known in the art.

While it is disclosed that the miscompare message indicators (e.g., 105a, 110a, 115a, 120a, and 130a) are presented by the exemplary PFD 100, one skilled in the art will readily recognize the presentation of a miscompare message indicator is not limited to a PFD, such as the PFD 100. For example, the principles of present invention may also be applied to a Multi-Function Display (MFD) system and other such systems as known in the art.

Furthermore, while it is disclosed that the miscompare message indicators (e.g., 105a, 110a, 115a, 120a, and 130a) are presented by the exemplary PFD 100, one skilled in the art will readily recognize the presentation of a miscompare message indicator is not limited to a single PFD, such as the PFD 100. The principles of present invention may also be applied to more than one PFD. For example, a cockpit may have a first PFD for a pilot and a second PFD for a co-pilot. In this example, a miscompare message indicator presented on the first PFD is also presented on the second PFD, and vice versa.

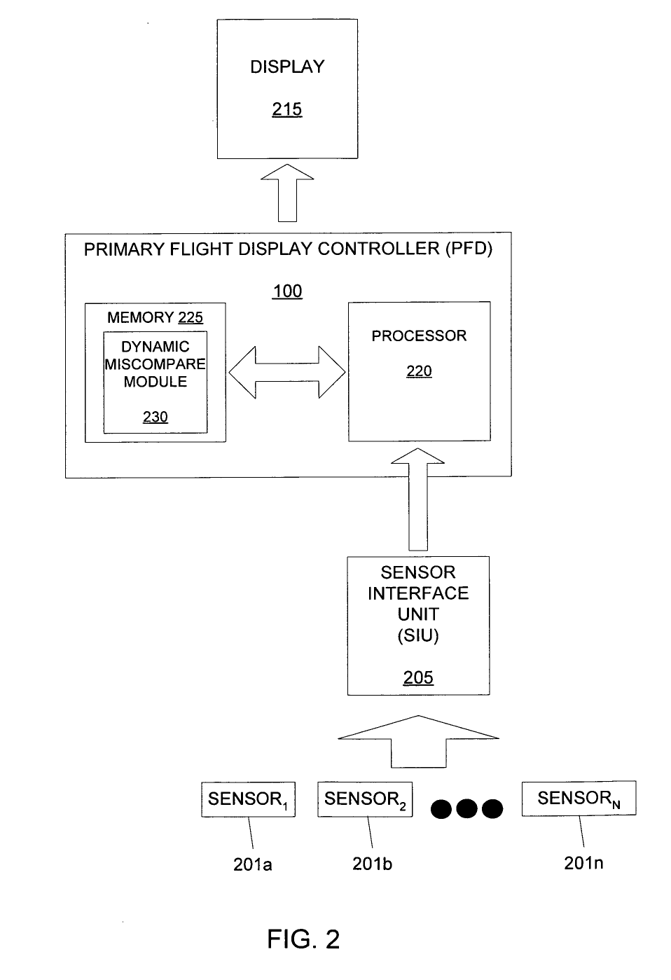

FIG. 2 is a block diagram of an exemplary Primary Flight Display (PFD) system 100 which includes an exemplary dynamic miscompare module 230 in accordance with the principles of the present invention. The PFD system 100 includes a Sensor Interface Unit (SIU) 205, a controller 210, and a display 215. The controller 210 further includes a digital processor 220, a memory 225 and a dynamic miscompare module 230. The processor 220 loads from the memory 225 the dynamic miscompare module 230. The processor-memory configuration of FIG. 2 is only an exemplary illustration, one of ordinary skill in the art will readily appreciate the present invention is not limited to the illustrated processor-memory configuration, but may employ other configurations known in the art. For example, the memory 225 may be “on die,” i.e., the processor 220 and the memory 225 may be integrated onto a single integrated circuit (IC).

Sensor signals from various sensors 201a, 201b . . . 201n (e.g., an airspeed sensor) are collected by a Sensor Interface Unit (SIU) 205. The SIU 205 in turn provides a plurality of instrumentation data (i.e., at least a first datum and a second datum) to the processor 220. The processor 220 executes the dynamic miscompare module 230 on the received plurality of instrumentation data. The display 215 then displays or otherwise indicates the output from the dynamic miscompare module 230.

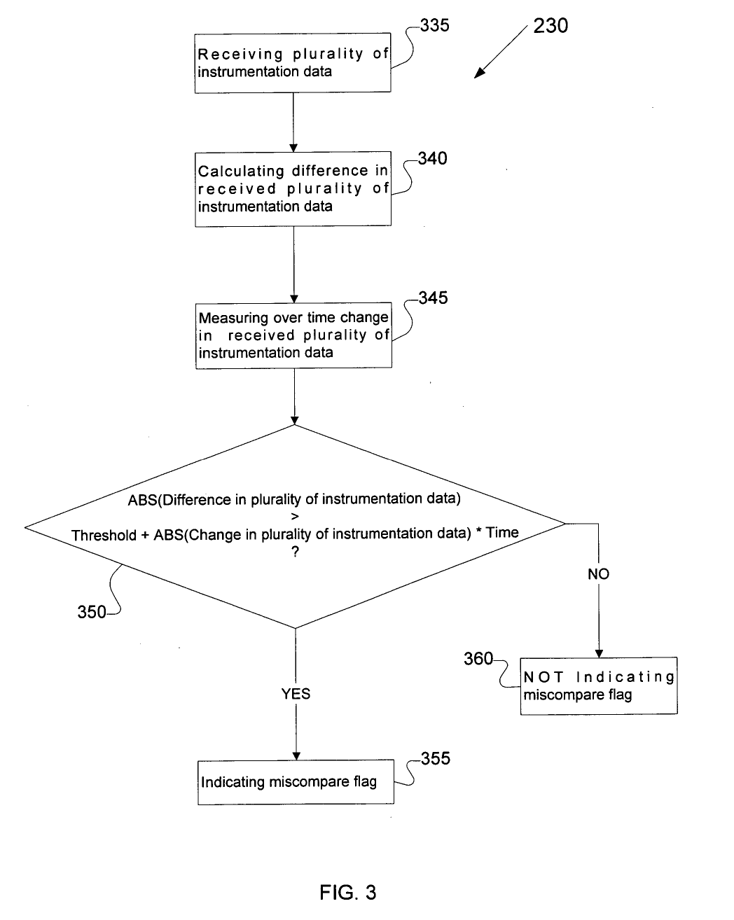

FIG. 3 is a flow chart of a dynamic miscompare module 230. At step 335, the dynamic miscompare module 230 receives a plurality of instrumentation data from sensors 201a, 202b . . . 201n (see FIG. 2). For example, the dynamic miscompare module 230 receives a first indicated airspeed datum from a first airspeed sensor, a second indicated airspeed datum from a second airspeed sensor, and a third indicated airspeed datum from a third airspeed sensor. As such, the received plurality of instrumentation data consists of the first indicated airspeed datum, second indicated airspeed datum, and the third indicated airspeed datum, from the first, second, and third indicated airspeed sensors, respectively.

In addition to indicated airspeed, the received plurality of instrumentation data also corresponds to other flight parameters such as pitch attitude, roll attitude, magnetic heading, and pressure altitude. One skilled in the art will readily recognize other flight parameters are within the contemplation of the present invention.

At step 340, the dynamic miscompare module 230 calculates a difference in the received plurality of instrumentation data. Continuing with the previous example, a first difference in indicated airspeed is calculated from the first indicated airspeed datum and the second indicated airspeed datum. Similarly, a second difference in indicated airspeed is calculated from the second indicated airspeed datum and the third indicated airspeed datum, and so on.

At step 345, the dynamic miscompare module 230 measures over time a change in the received plurality of instrumentation data.

At step 350, the dynamic miscompare module 230 compares the difference in the received plurality of instrumentation data calculated in step 340 with the measured change in the received plurality of instrumentation data measured in step 345. If the absolute value of the calculated difference is greater than the total of a threshold value and the product of the measured change and time (or scale factor), then a miscompare message indicator is indicated at step 355. If, however, the absolute value of the calculated difference is less than the total of a threshold value and the product of the measured change and time, then a miscompare message indicator is not indicated at step 360.

The threshold value used in the comparing step 350 may be statically defined or constant. For example, the threshold value is set based on known errors of the instrumentation datum which do not vary based on flight conditions. Alternatively, the threshold value used in the comparing step 350 may be dynamically defined or varied with one or more flight parameters. For example, a threshold value for a pressure altitude datum is 50 feet at altitudes below 5,000 feet, while the threshold value is 150 feet at altitudes above 30,000 feet. As another example, a threshold value for a pressure altitude datum varies linearly from 50 feet to 150 feet for altitudes between 5,000 feet and 30,000 feet. As such, the threshold for the pressure altitude datum varies with the pressure altitude parameter—the greater the pressure altitude, the greater the threshold for the pressure altitude datum.

The outcome of the comparing step 350 depends not only on a calculated difference in a received plurality of instrumentation data, but also on a measured change in the received plurality of instrumentation data. For example, a miscompare message indicator for a roll attitude datum is not displayed despite a calculated difference in roll attitude data exceeding a threshold value for roll attitude when a measured change in roll attitude data is large. This occurs, for example, when an aircraft is undergoing aggressive maneuvers or otherwise experiencing rapid changes in flight. In this way, the comparing step 350 is dynamic and varies depending on how the aircraft is being flown.

To further illustrate the comparing step 350 consider the following. When an aircraft is in level flight (i.e., zero degrees to the horizon) the pitch attitude of the aircraft does not change over time. In other words, the change in pitch or the pitch rate of the aircraft is zero degrees per second. Other units of measure such as, but limited to, radians per second may also be used. When the aircraft, however, is in a steep climb or drive as to quickly change altitude, the pitch attitude of the aircraft changes by a large amount over a short period of time. As such, the pitch rate of the aircraft is large when the aircraft is in a steep climb or drive. In contrast, when the aircraft is gradually ascending or descending, as to slowly change altitude, the pitch attitude of the aircraft changes by a small amount over a long period of time. As such, the pitch rate of the aircraft is small when the aircraft is gradually ascending or descending.

By way of example, the dynamic miscompare module 230 at the comparing step 350 compares whether the absolute difference in pitch attitude data is greater than the sum of 3.0 degrees and the absolute pitch rate multiplied by 0.3 seconds. As an example, assume the aircraft has a pitch rate of 30 degrees per second when the aircraft is in a steep climb and a pitch rate of 3 degrees per second when the aircraft is in a gradual climb. Accordingly, a miscompare message indicator is displayed at step 355 when the absolute difference in pitch data is greater than 12 degrees when the aircraft is in a steep climb. In contrast, when the aircraft is in a gradual climb, a miscompare message indicator is displayed when the absolute difference in pitch data is greater than 3.9 degrees.

As illustrated by the above example, a greater difference in instrumentation data is acceptable or tolerable when a change in instrumentation data is great. Conversely, a smaller difference in instrumentation data is acceptable or tolerable when a change in instrumentation data is small. As such, under certain circumstances a miscompare condition arises while in other circumstances a miscompare condition does not arises.

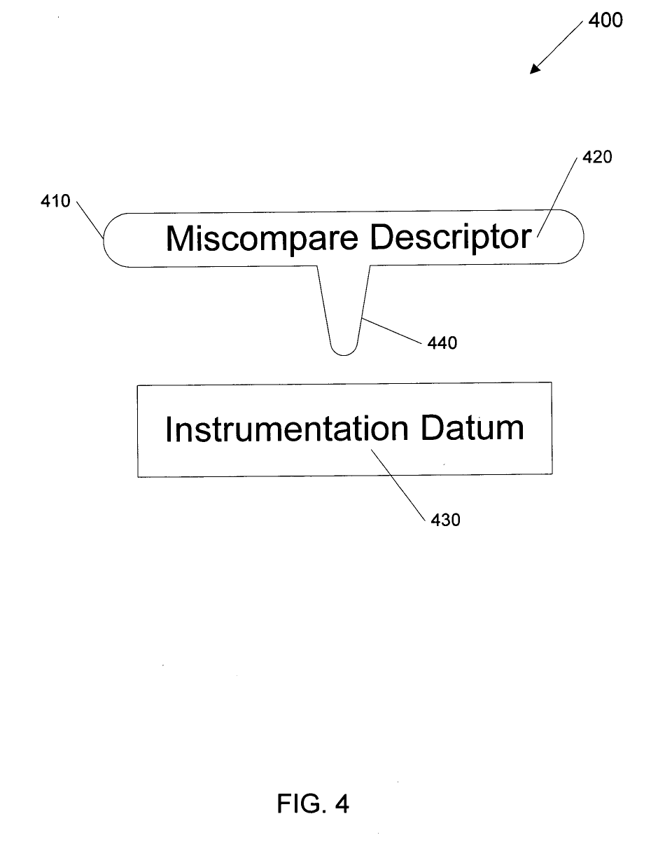

Referring to FIGS. 3 and 4, the dynamic miscompare module 230 indicates a miscompare message indicator 400 upon determining a miscompare condition in step 350. The miscompare message indicator 400 includes a miscompare cue 410 and a miscompare descriptor 420. The balloon-like shape of the miscompare cue 410 is merely illustrative and is not intended to limit the present invention. The miscompare cue 410 may assume a variety of shapes, e.g., a rectangle, a square, an ellipse, a circle, a triangle, or a polygon. Alternatively, the miscompare cue 410 may have a diagrammatical shape, e.g., a callout balloon. One of ordinary skill in the art will readily appreciate the general principles of the present invention are not limited by the shape selected for the miscompare cue 410.

Still referring to FIG. 4 the miscompare descriptor 420 may be English text (e.g., “Heading Miscompare”), but may also be non-English text, e.g., traditional Chinese. The miscompare descriptor 420 may also be an alphanumerical character string, e.g., “HDG MIS=10 DEG.” Although the miscompare descriptor 420 is described as being text or an alphanumerical character string, combinations thereof known in the art are also within the contemplation of the present invention. Similarly, symbols, graphics and combinations thereof known in the art are also with the contemplation of the present invention. One of ordinary skill in the art will readily appreciate these embodiments and combinations thereof are all within the contemplation of the present invention.

Additionally, the miscompare descriptor 420 is not necessarily limited to describing a miscompare condition (e.g., “Heading Miscompare”), but may also provide status (e.g., “Heading Comparator Enabled”) or a query for a response, e.g., “Heading Miscompare, Ignore? [Y/N].”

Forming an indicated miscompare message indicator 400 as a miscompare cue 410 and a miscompare descriptor 420 allows an operator to readily discern, ascertain, and comprehend which instrumentation datum 430 is unreliable. For example, shaping the miscompare cue 410 as a rectangle alerts an operator of a miscompare condition visually. As another example, printing the miscompare descriptor 420 as English text alerts an operator of a miscompare condition textually.

Referring to FIGS. 3 and 4, the dynamic miscompare module 230 indicates a miscompare message indicator 400 upon determining a miscompare condition in step 350. In one embodiment of the present invention, the dynamic miscompare module 230 interposes between the miscompare message indicator 400 and the instrumentation datum 430 a leader 440 when a miscompare condition arises.

For example, when a miscompare condition for airspeed arises, the dynamic miscompare module 230 interposes a leader between a miscompare message indicator for airspeed and an instrumentation datum for airspeed. As such, in addition to being alerted by the miscompare message indicator for airspeed itself, an operator is also alerted to the miscompare condition for airspeed by the leader interposed between of the miscompare message indicator for airspeed and the instrumentation datum for airspeed.

Alternatively, in another embodiment of the present invention, the dynamic miscompare module 230 locates the miscompare message indicator 400 proximally to the instrumentation datum 430 when a miscompare condition arises and the instrumentation datum 430 is unreliable.

For example, when a miscompare condition for airspeed arises, the dynamic miscompare module 230 locates a miscompare message indicator for airspeed proximally to an instrumentation datum for airspeed. As such, in addition to being alerted by the miscompare message indicator for airspeed itself, an operator is also alerted to the miscompare condition for airspeed by the proximity of the miscompare message indicator for airspeed to the instrumentation datum for airspeed.

Rather than limiting the present invention, interposing a leader between the miscompare message indicator 400 and the instrumentation datum 430, and locating the miscompare message indicator 400 proximally to the instrumentation datum 430 are examples of the dynamic miscompare module 230 indicating a miscompare condition. Other examples exist and are within the contemplation of the present invention. For example, the dynamic miscompare module 230 may indicate a miscompare condition with an auditory indicator such as a buzzer or a recorded voice.

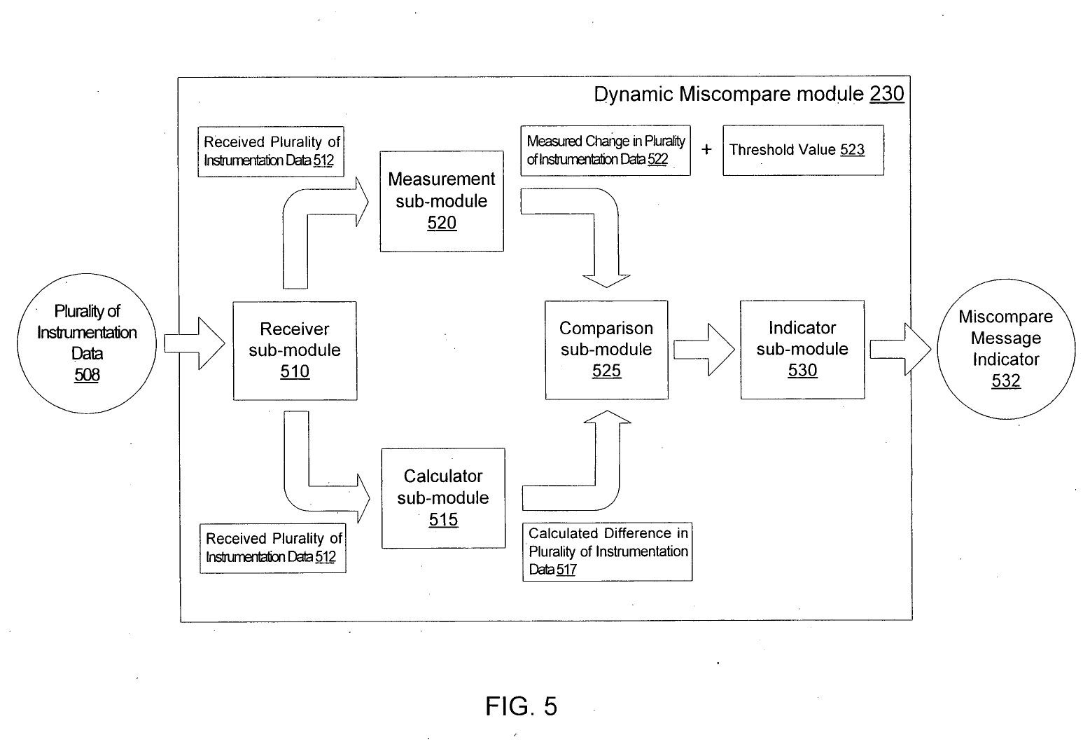

FIG. 5 is a block diagram illustrating the exemplary dynamic miscompare module 230 of FIG. 2. The dynamic miscompare module 230 includes a receiver sub-module 510, a calculator sub-module 515, a measurement sub-module 520, a comparison sub-module 525 and an indicator sub-module 530. Alternatively, some or all of the aforementioned sub-modules may not be co-located, but may be remotely located and connected to one another via a data communication bus (not shown).

A plurality of instrumentation data 508 is received by the receiver sub-module 510 resulting in a received plurality of instrumentation data 512.

The calculator sub-module 515 calculates a difference in the received plurality of instrumentation data 512. The result of the calculation is a calculated difference in plurality of instrumentation data 517.

The measurement sub-module 520 measures over time a change in the received plurality of instrumentation data 512. The result of the measurement is a measured change in plurality of instrumentation data 522.

The comparison sub-module 525 compares the calculated difference in plurality of instrumentation data 517 to a total (or a sum) of the measured change in plurality of instrumentation data 522 and a threshold value 523.

When the calculated difference in plurality of instrumentation data 517 is greater than the total of the measured change in plurality of instrumentation data 522 and the threshold value 523, the indicator sub-module 530 indicates a miscompare message indicator 532. The miscompare message indicator 532 provides an indication of the reliability of an instrumentation datum.

While this invention has been particularly shown and described with references to preferred embodiments thereof, it will be understood by those skilled in the art that various changes in form and details may be made therein without departing from the scope of the invention encompassed by the appended claims.

For example, in addition to indicating a flight parameter miscompare (i.e., a miscompare condition in a flight parameter such as pitch attitude) the dynamic miscompare module of the present invention may also indicate a miscompare condition in Very High Frequency (VHF) navigation information.

For example, the dynamic miscompare module indicates or otherwise presents a localizer miscompare in an event a first horizontal deviation from a first identically tuned navigation radio and at least one second horizontal deviation from a second identically tuned navigation radio do not satisfy a condition. By way of example, the dynamic miscompare module indicates the localizer miscompare in an event the first and second horizontal deviations are valid and differ by more than 0.0775 depth of differential modulation (ddm).

In another example, the dynamic miscompare module indicates or otherwise presents a glideslope miscompare in an event a first vertical deviation from a first identically tuned navigation radio and at least one second vertical deviation from a second identically tuned navigation radio do not satisfy a condition. By way of example, the dynamic miscompare module indicates the glideslope miscompare in an event the first and second vertical deviations are valid and differ by more than 0.0875 ddm, but does not indicate the glideslope miscompare during a backcourse.

In yet another example, the dynamic miscompare module indicates or otherwise presents a VHF Omnirmage (VOR) miscompare in an event a first VOR bearing from a first identically tuned navigation radio and at least one second VOR bearing from a second identically tuned navigation radio do not satisfy a condition. By way of example, the dynamic miscompare module indicates the VOR miscompare in an event the first and second VOR bearings are valid and differ by more than 4 degrees, but not indicating a VOR miscompare in an event the first and second VOR bearings are changing by more than 3 degrees/second.

In yet another example embodiment, the dynamic miscompare does not indicate a miscompare message indicator for a period of time in an event a navigation frequency used by the first navigation radio and at least one second navigation radio is changed.

In still yet another example embodiment, the dynamic miscompare does not indicate a miscompare message indicator in an event a miscompare condition is indicated from a period of time.

In still yet another example embodiment, the dynamic miscompare does not indicate a miscompare message indicator in an event that an airspeed is less than a minimum steady flight speed at which an airplane is controllable in a landing configuration (or VS0)+5 knots.

What is claimed is:

1. A computer implemented method for indicating instrumentation datum reliability comprising:
receiving a plurality of instrumentation data;
calculating a difference in the received plurality of instrumentation data;
measuring over time a change in the received plurality of instrumentation data;
comparing the calculated difference to a total of the measured change and a threshold value; and
indicating a miscompare message indicator when the calculated difference exceeds the total of the measured change and the threshold value, the indicated miscompare message indicator providing an indication of reliability of an instrumentation datum.

2. The method of claim 1 wherein the receiving includes collecting instrumentation data corresponding to any one of flight parameters including pitch attitude, roll attitude, magnetic heading, indicated airspeed, and pressure altitude.

3. The method of claim 1 wherein the comparing includes varying the threshold value with at least one flight parameter.

4. The method of claim 1 wherein the comparing includes setting the threshold value based on a known error in the instrumentation datum.

5. The method of claim 1 wherein the indicating includes forming a miscompare cue and a miscompare descriptor.

6. The method of claim 1 wherein the indicating includes interposing a leader between the miscompare message indicator and the instrumentation datum.

7. The method of claim 1 wherein the indicating includes locating the miscompare message indicator proximal to the instrumentation datum.

8. The method of claim 5 wherein the forming includes shaping the miscompare cue as any one of geometrical shapes including a rectangle, a square, an ellipse, a circle, a triangle, and a polygon.

9. The method of claim 5 wherein the forming includes shaping the miscompare cue as a callout balloon.

10. The method of claim 5 wherein the forming includes printing the miscompare descriptor as any one of English text, non-English text, and an alphanumerical character string.

11. An apparatus for indicating instrumentation datum reliability comprising:
a receiver sub-module which receives a plurality of instrumentation data;
a calculator sub-module in communication with the receiver sub-module which calculates a difference in the received plurality of instrumentation data;
a measurement sub-module in communication with the receiver sub-module which measures over time a change in the received plurality of instrumentation data;
a comparison sub-module in communication with the calculator sub-module and the measurement sub-module, the comparison sub-module compares the calculated difference calculated by the calculator sub-module to a total of the measured change measured by the measurement sub-module and a threshold value; and
an indicator sub-module in communication with the comparison sub-module which indicates a miscompare message indicator when the calculated difference exceeds the total of the measured change and the threshold value, the indicated miscompare message indicator provides an indication of reliability of an instrumentation datum.

12. The apparatus of claim 11 wherein the receiver sub-module is configured to collect instrumentation data corresponding to any one of flight parameters including pitch attitude, roll attitude, magnetic heading, indicated airspeed, and pressure altitude.

13. The apparatus of claim 11 wherein the threshold value is a variable dependent on at least one flight parameter.

14. The apparatus of claim 11 wherein the threshold value is a constant set based on a known error in the instrumentation datum.

15. The apparatus of claim 11 wherein the indicated miscompare message indicator is a miscompare cue and a miscompare descriptor.

16. The apparatus of claim 11 wherein the indicator sub-module is configured to interpose a leader between the miscompare message indicator and the instrumentation datum.

17. The apparatus of claim 11 wherein the indicator sub-module is configured to locate the miscompare message indicator proximal to the instrumentation datum.

18. The apparatus of claim 15 wherein the miscompare cue is any one of geometrical shapes including a rectangle, a square, an ellipse, a circle, a triangle, and a polygon.

19. The apparatus of claim 15 wherein the miscompare cue is a callout balloon.

20. The apparatus of claim 12 wherein the miscompare descriptor is any one of English text, non-English text, and an alphanumerical character string.

21. A computer-readable storage medium containing a set of instructions for indicating instrumentation datum reliability comprising:
a receiver routine coded to receive a plurality of instrumentation data;
a calculator routine operatively associated with the receiver routine, the calculator routine coded to calculate a difference in the received plurality of instrumentation data;
a measurement routine operatively associated with the receiver routine, the measurement routine coded to measure over time a change in the received plurality of instrumentation data;
a comparison routine operatively associated with the calculator routine and the measurement routine, the comparison routine coded to compare the calculated difference calculated by the calculator routine to a total of the measured change measured by the measurement routine and a threshold value; and
an indicator routine operatively associated with the comparison routine, the indicator routine coded to indicate a miscompare message indicator when the calculated difference exceeds the total of the measured change and the threshold value, the indicated miscompare message indicator provides an indication of reliability of an instrumentation datum.
